(19) United States
(12) Patent Application Publication
(10) Pub. No.: US 2025/0007242 A1
(43) Pub. Date: Jan. 2, 2025

(54) System and Method for Phase Stabilization of Optical Sources

(71) Applicant: Xanadu Quantum Technologies Inc., Toronto (CA)

(72) Inventor: Varun Dilip Vaidya, Toronto (CA)

(21) Appl. No.: 18/342,272

(22) Filed: Jun. 27, 2023

(51) Int. Cl. H01S 5/068; H01S 5/00; H01S 5/062

(52) U.S. Cl. CPC H01S 5/06821; H01S 5/0078; H01S 5/06233; H01S 5/06808

(57) ABSTRACT

There is described a system and method for controlling the phase relationship between two optical signals and an optical frequency comb. Two optical mixers are configured to generate beat signals based on the optical signals and the optical frequency comb. A first detector is configured to measure the relative phase between the two beat signals, and a second detector is configured to measure the relative phase between one of the beat signals and a reference signal. One or more control signals based on the measurements are then used to control the phases of the optical signals to maintain a desired phase relationship between the optical signals and the optical frequency comb. The system and method can be configured such that the optical frequency comb is symmetric about a central frequency, and the phase relationship is resilient to noise induced by the generation of the optical frequency comb.

### CROSS-REFERENCE TO RELATED APPLICATIONS

This is the first patent application related to the invention disclosed herein.

### BACKGROUND OF THE INVENTION

The present disclosure relates to optics, and in particular to a system and method for stabilizing the phase of optical signals.

Precise control of the phase of optical signals is required for a wide range of applications including optical communication, quantum optics, and photonic quantum computing. In some applications, the phase of two or more optical sources must be stabilized relative to each other. One example of this can be found in the generation of squeezed states of light (also referred to herein as “squeezed light”), which is widely used in quantum optics and photonic quantum computing. For example, squeezed light can be used to produce photonic quantum bits (qubits) across several encoding regimes (single-rail, dual-rail, GKP, etc.).

In one example of squeezed light production referred to as degenerate squeezed light, light from two optical pumps at two different frequencies is propagated through coupled ring resonators, resulting in an output of squeezed light at a frequency equal to the average of the frequencies of the two optical pumps. In order for the degenerate squeezed light to be produced with a stable phase, the phases of the optical pumps must maintain a consistent mutual relationship which must be precisely controlled. Further, in some applications, the phase of the degenerate squeezed light must also be controlled relative to a local oscillator light source (for homodyne detection, for example). While methods that exist in the art disclose how to control the phase of an optical pump with respect to a local oscillator by way of a frequency comb, these methods are susceptible to noise-induced changes in the comb tooth spacing. It is therefore desirable to create a novel approach to the precise control of the phase of two optical sources with respect to a third optical source that is resilient to this noise.

### SUMMARY OF THE INVENTION

The present disclosure provides a system and method for controlling the phase relationship between two optical signals and an optical frequency comb. In some embodiments, the optical frequency comb can be symmetric about a central frequency, and the phase relationship between the two optical signals and the central frequency can be resilient to noise in the comb tooth spacing of the optical frequency comb. The system and method provided herein can be used, for example, in quantum optics and photonic quantum computing applications, including the generation of squeezed light.

In accordance with a first aspect of the present disclosure, there is provided a system comprising: a first optical source configured to generate a first optical signal; a second optical source configured to generate a second optical signal; a first optical mixer configured to generate a first beat signal based on an optical frequency comb and the first optical signal; a second optical mixer configured to generate a second beat signal based on the optical frequency comb and the second optical signal; a first detector configured to output a first measurement signal based on the first and second beat signals; a second detector configured to output a second measurement signal based on the second beat signal and a reference signal; and a signal processor configured to generate one or more control signals based on the first and second measurement signals for adjusting one or more of the first optical source and the second optical source to maintain a phase relationship between the first optical signal, the second optical signal, and the optical frequency comb.

Further in accordance with the first aspect, the first optical signal may have a first frequency; the second optical signal may have a second frequency; the first optical mixer may be configured to generate the first beat signal based on the first optical signal and a first comb tooth of the optical frequency comb nearest to the first frequency; and the second optical mixer may be configured to generate the second beat signal based on the second optical signal and a second comb tooth of the optical frequency comb nearest to the second frequency.

Further in accordance with the first aspect, the system may comprise a modulator configured to generate the frequency comb, the frequency comb being symmetric about a comb source frequency. In some embodiments, the first optical signal has a first phase ϕ₁ given by ϕ₁=2πf₁t+φ₁, where f₁ is a first frequency, t represents time, and φ₁ is a first phase offset; the second optical signal has a second phase ϕ₂ given by ϕ₂=2πf₂t+φ₂, where f₂ is a second frequency, t represents time, and ϕ₂ is a second phase offset; and the phase relationship is such that the average of the first frequency f₁ and the second frequency f₂ is substantially equal to the comb source frequency. In some embodiments, the phase relationship is at least partially resilient to noise induced by the modulator. In some further embodiments, the frequency comb is generated based on a local oscillator signal, and the comb source frequency is a local oscillator frequency.

Further in accordance with the first aspect, the first optical mixer may comprise a 50:50 beamsplitter and the second optical mixer may comprise a 50:50 beamsplitter.

Further in accordance with the first aspect, the first beat signal and second beat signal may each comprise a primary beat and a plurality of secondary beats at frequencies greater than the primary beat.

Further in accordance with the first aspect, the reference signal may be one of a radio-frequency reference signal and a microwave reference signal.

In accordance with a second aspect of the present disclosure, there is provided a method comprising: generating a first beat signal based on an optical frequency comb and a first optical signal; generating a second beat signal based on the optical frequency comb and a second optical signal; measuring the phase of the first beat signal with respect to the second beat signal to produce a first phase measurement signal; measuring the phase of the second beat signal with respect to a reference signal to produce a second phase measurement signal; and controlling one or more of the first optical signal and the second optical signal based on the first and second phase measurement signals to maintain a phase relationship between the first optical signal, the second optical signal, and the optical frequency comb.

Further in accordance with the second aspect, the first optical signal may have a first frequency; the second optical signal may have a second frequency; the generating of the first beat signal may be based on the first optical signal and a first comb tooth of the optical frequency comb nearest to the first frequency; and the generating of the second beat signal may be based on the second optical signal and a second comb tooth of the optical frequency comb nearest to the second frequency.

Further in accordance with the second aspect, the optical frequency comb may be generated such that it is symmetric about a central frequency. In some embodiments, the first optical signal has a first phase ϕ₁ given by ϕ₁=2πf₁t+φ₁, where f₁ is a first frequency, t represents time, and φ₁ is a first phase offset; the second optical signal has a second phase ϕ₂ given by ϕ₂=2πf₂t+φ₂, where f₂ is a second frequency, t represents time, and φ₂ is a second phase offset; and the phase relationship is such that the average of the first frequency f₁ and the second frequency f₂ is substantially equal to the central frequency. In some further embodiments, the phase relationship is at least partially resilient to noise induced in the generating of the optical frequency comb.

Further in accordance with the second aspect, one or more of the first beat signal and the second beat signal may be filtered to remove high-frequency beats.

### BRIEF DESCRIPTION OF THE DRAWINGS

Reference will now be made, by way of example, to the accompanying figures which show example embodiments of the present application, and in which:

FIG. 1 shows a schematic of an apparatus for generating degenerate squeezed light by way of an optical phase stabilization system, in accordance with one or more embodiments;

FIG. 2 shows a system-level block diagram of an exemplary phase stabilization system, in accordance with one or more embodiments;

FIG. 3 shows the production of a frequency comb by an optical modulator, in accordance with one or more embodiments;

FIG. 4 shows the frequency spectrum of a frequency comb, in accordance with one or more embodiments;

FIG. 5 shows an illustrative example of the production of a beat signal when two signals of similar frequencies interfere with each other, in accordance with one or more embodiments;

FIG. 6 shows the operation of an optical mixer upon receiving an optical frequency comb and a monochromatic optical signal, in accordance with one or more embodiments;

FIG. 7 shows a magnified view of the frequency spectrum of a frequency comb near the frequencies of two optical signals, in accordance with one or more embodiments; and

FIG. 8 shows a flowchart for a method for stabilizing the phase of two optical signals using a frequency comb, in accordance with one or more embodiments.

Like reference numerals are used throughout the figures to denote similar elements and features. While aspects of the invention will be described in conjunction with the illustrated embodiments, it will be understood that it is not intended to limit the invention to such embodiments. Unless otherwise specifically noted, articles depicted in the drawings are not necessarily drawn to scale.

### DETAILED DESCRIPTION OF THE INVENTION

The present disclosure is made with reference to the accompanying drawings, in which embodiments are shown. However, many different embodiments may be used, and thus the description should not be construed as limited to the embodiments set forth herein. Rather, these embodiments are provided so that this application will be thorough and complete. Wherever possible, the same reference numbers are used in the drawings and the following description to refer to the same elements. Separate boxes or illustrated separation of functional elements of illustrated systems and devices does not necessarily require physical separation of such functions, as communication between such elements may occur by way of messaging, function calls, shared memory space, and so on, without any such physical separation. As such, functions need not be implemented in physically or logically separated platforms, although such functions are illustrated separately for ease of explanation herein. Different devices may have different designs, such that although some devices implement some functions in fixed function hardware, other devices may implement such functions in a programmable processor with code obtained from a machine-readable medium. Lastly, elements referred to in the singular may be plural and vice versa, except where indicated otherwise either explicitly or inherently by context.

Squeezed light can be exploited for its quantum properties and is therefore used extensively in quantum optics, including quantum communication and photonic quantum computing, for example. There are a number of ways in which squeezed light can be produced, often involving the use of nonlinear optical materials (e.g., sodium vapor, silicon dioxide, ferroelectric crystal, etc.).

In some methods of squeezed light generation, one or more silicon nitride microring resonators are used, which have significant third-order optical nonlinearity and are suitable for generating squeezed light via spontaneous four-wave mixing. Pumped lasers at two different frequencies can be propagated through a microring resonator to produce degenerate squeezed light at a frequency equal to the average of the two pumped laser frequencies. In some cases, an auxiliary microring resonator coupled to the main microring resonator can be used to suppress unwanted parasitic parametric fluorescence. This procedure for the generation of degenerate squeezed light is described in U.S. Pat. No. 10,649,307 entitled “Integrated devices for squeezed light generation,” the contents of which are incorporated herein in their entirety.

The phase of optical signals travelling through a medium (for example, a fiber optic cable) may be affected by changes in the length and refractive index of the medium due to environmentally induced noise (temperature changes, vibrations, etc.). When working with multiple optical signals, each signal can be affected differently by this noise. In the above-described method of degenerate squeezed light generation, as well as in other methods of squeezed light generation, it may be desirable to stabilize the phase of the two pumped lasers with respect to each other in a manner that is resilient to environmentally induced noise in order to generate squeezed light. It may also be desirable to stabilize the phase of the two pumped lasers with respect to a third optical source (such as a local oscillator, for example) for subsequent detection of the generated squeezed light (e.g., homodyne detection, heterodyne detection, etc.).

The disclosure set forth herein provides a system and a method for phase stabilization of two optical sources with respect to one another and with respect to a third optical source while being resilient to environmentally induced noise. In some embodiments, there is provided a method for phase control of two optical sources by leveraging the comb tooth spacing of a frequency comb while being resilient to noise-induced changes in the comb tooth spacing.

Some embodiments set forth herein use a frequency comb with a central frequency determined by a comb source signal. Laser light from two optical sources can then be mixed with the frequency comb to generate two respective beat signals. These beat signals can then be measured with respect to each other and with respect to a reference signal. The relative phase of the optical signals from the two optical sources with respect to the phase of the comb source signal can therefore be determined and subsequently used to control the optical sources, as described in the present disclosure.

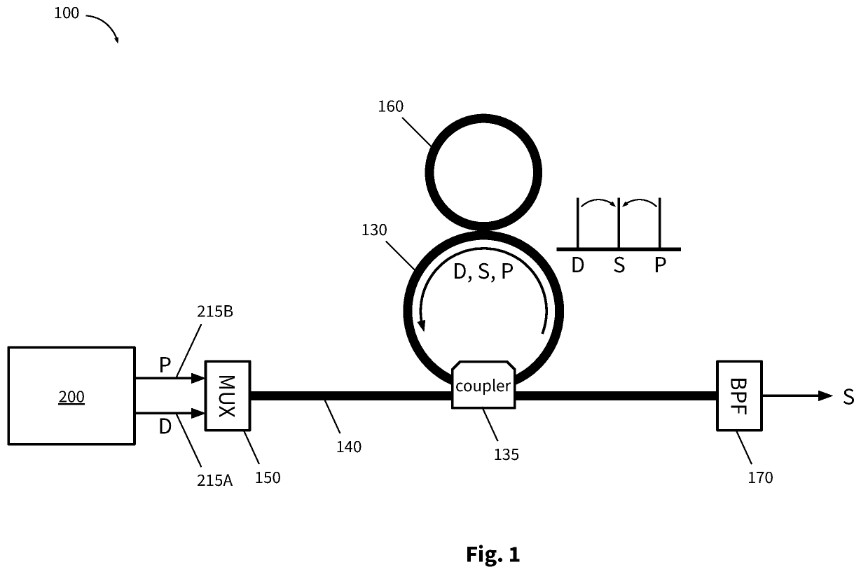

FIG. 1 shows a schematic of an exemplary apparatus 100 including a main resonator 130 and an auxiliary resonator 160 for generating degenerate squeezed light via four-wave mixing, in accordance with an embodiment. The apparatus 100 includes a phase stabilization system 200 providing two optical signals 215A and 215B. In the case of the exemplary apparatus 100, the optical signals 215A and 215B may be pump laser signals. The two optical signals 215A and 215B are combined by a mixing element (MUX) 150 into a waveguide 140, which is coupled to the main resonator 130 via a coupler 135. In some embodiments, the MUX 150 can be a dense-wavelength division multiplexer (DWDM). The coupler 135 can be, for example, a fixed coupler (e.g., point coupler or racetrack coupler) or a tunable coupler (e.g., MZI-based coupler). The optical signal 215A has a wavelength corresponding to the resonance D within the main resonator 130, while the optical signal 215B has a wavelength corresponding to the resonance P within the main resonator 130. Dual-pumped parametric fluorescence in the main resonator 130 induces a squeezed state in the S resonance, which has (after accounting for nonlinear detunings) a frequency equal to the average frequency of the D and P modes. This squeezed state yields a squeezed light output propagating in the waveguide 140.

A bandpass filter (BPF) 170 is employed to remove the unwanted pump beams. The BPF can be implemented interferometrically by coherent displacement or via passive wavelength filtering, for example. Accordingly, the output of the apparatus 100 includes only squeezed light, the temporal mode structure of which can be controlled by the properties of the optical signals 215A and 215B.

The apparatus 100 also includes the auxiliary resonator 160 to further tune the main resonator 130 to suppress unwanted four-wave mixing processes by coupling to appropriate resonances and corrupting their ability to generate spurious light in the S mode. The auxiliary resonator 160 has a different free spectral range from the main resonator 130 and is employed to selectively split, detune, and degrade the quality factor of the extra resonance involved, thereby suppressing the unwanted process while preserving the desired squeezing interaction. Alternatively or in addition, an MZI-based coupler to the main resonator 130 can provide some independent control over the quality factors of different resonances, thereby allowing the efficiencies of competing processes to be manipulated.

As the properties of the squeezed light are determined by the phase of the optical signals 215A and 215B, the phase stabilization system 200 is used to maintain a desired phase relationship between the two optical signals while being resilient to environmentally induced noise, as disclosed herein.

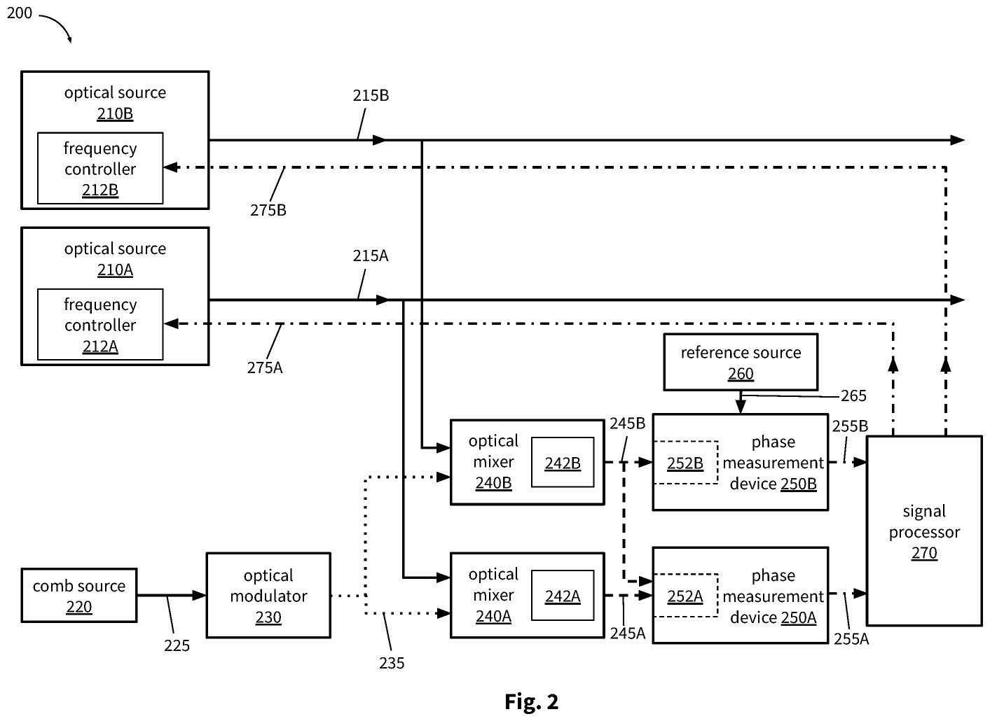

FIG. 2 illustrates a system-level block diagram of an exemplary phase stabilization system 200 in accordance with the present disclosure. The system 200 includes two optical sources 210A and 210B each generating respective optical signals 215A and 215B. Each optical source 210A, 210B also includes a respective frequency controller 212A, 212B. In some embodiments, the optical sources 210A and 210B can be tunable lasers, such as external cavity diode lasers, fiber lasers, self-injection-locked lasers, fiber Bragg grating lasers, or any other type of tunable lasers. The phase ϕ of a signal is given by ϕ=2πft+φ, where f is the frequency, t is time, and φ is the phase offset. The optical signals 215A and 215B have respective frequencies f₁ and f₂, where f₁<f₂, which can be controlled by the frequency controllers 212A and 212B. The system 200 also includes a comb source 220 that generates a comb source signal 225 with a frequency fₛ, where f₁<fₛ<f₂. In some embodiments, the comb source 220 can be a local oscillator, and the comb source signal 225 can be a local oscillator signal. In some other embodiments, the comb source 220 can be a narrow linewidth laser, and the comb source signal 225 can be a narrow linewidth laser signal. The comb source signal 225 is input to an optical modulator 230 to produce a frequency comb 235. In some embodiments, the optical modulator 230 can be an amplitude modulator, phase modulator, or some combination thereof. For example, the optical modulator 230 can be an electro-optic modulator in some embodiments. Note that the frequency comb 235 is configured such that the frequency range of the comb teeth extends at least to f₁ and f₂. When used for the purposes of producing degenerate squeezed light as shown in FIG. 1, the phase stabilization system 200 can be configured such that f₁ and f₂ correspond to the resonances D and P.

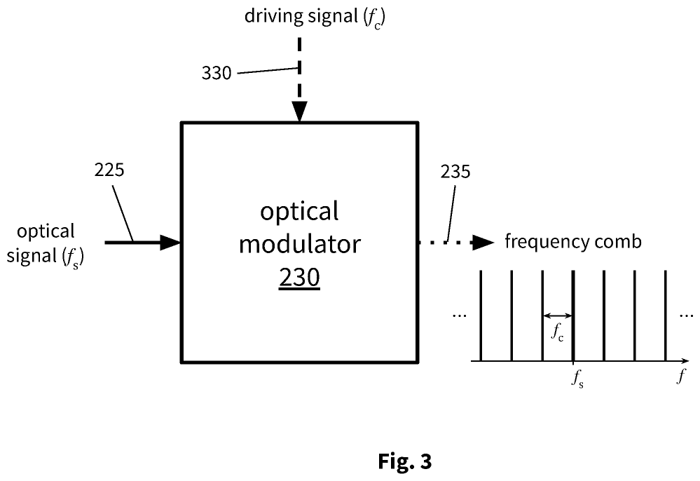

FIG. 3 illustrates the production of the frequency comb 235 by the optical modulator 230 from FIG. 2 in accordance with the present disclosure. The optical modulator 230 receives a comb source signal 225 with frequency fₛ and a driving signal 330 with frequency f_{c}, where f_{c}<<|f₁−fₛ|≈|f₂−fₛ|. In some embodiments, the driving signal 330 can be one of a radio-frequency signal and a microwave signal. The optical modulator 230 then generates a frequency comb 235 comprising multiple comb teeth, represented in FIG. 3 as vertical lines plotted along the horizontal frequency axis. The frequency comb 230 is symmetric about a central frequency equal to fₛ, while the spacing between the comb teeth is equal to f_{c}. f_{c} is also referred to herein as the comb frequency. While there are seven comb teeth shown in FIG. 3, it will be understood by those skilled in the art that the bandwidth of the frequency comb may extend above and below the frequency range shown.

Noise in the driving signal 330 can result in changes in f_{c}, therefore affecting the comb tooth spacing. However, it is noted that, due to the frequency comb being symmetric about the frequency of the comb source signal fₛ, any changes in the comb tooth spacing induced by noise in the driving signal are also symmetric about fₛ. The invention disclosed herein takes advantage of this symmetry, allowing the phase control of the optical sources 210A and 210B to be resilient to noise in the driving signal 330, as will be described below in this disclosure.

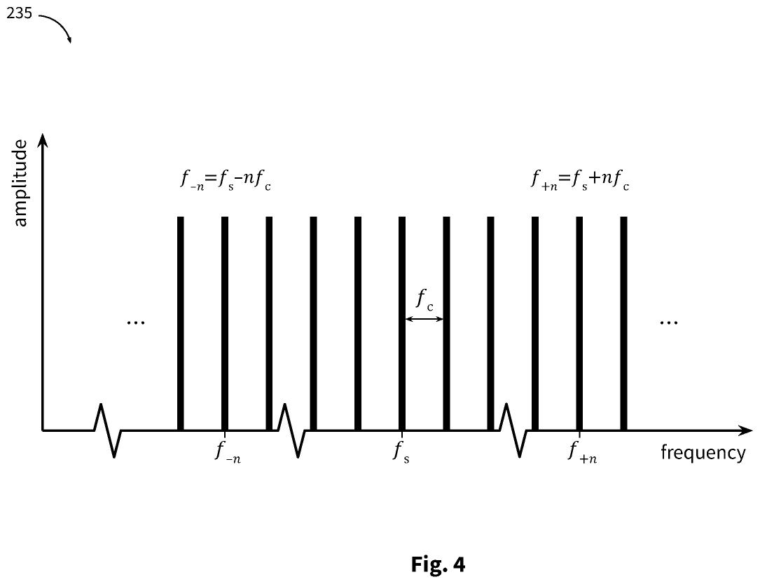

FIG. 4 illustrates a more detailed frequency spectrum of the frequency comb 235 in accordance with the present disclosure. The frequency comb 235 comprises a central frequency fₛ (i.e., equal to the frequency of the comb source signal) and a plurality of comb teeth separated by the comb frequency f_{c}. The comb teeth are spaced symmetrically about fₛ such that any changes in f_{c} are also symmetric about fₛ. Each comb tooth is labelled by an integer according to its distance from fₛ. For example, the comb tooth immediately to the right of fₛ is f₊₁ (i.e., f₊₁=fₛ+f_{c}), whereas the comb tooth immediately to the left of fₛ is f₋₁ (i.e., f₋₁=fₛ−f_{c}). In general, a comb tooth that is n multiples of f_{c} away from fₛ is labelled as f₊ₙ for frequencies greater than fₛ and f₋ₙ for frequencies less than fₛ, where n is a positive integer.

In practice, the comb teeth as depicted in FIG. 4 have finite widths and are not ideal δ functions. However, it is noted that the widths of the peaks (which may be as small as 3 Hz in some embodiments, and up to 10 kHz in other embodiments) are small compared to the comb frequency f_{c} (which may be 30 GHz in some embodiments, for example). As will be understood by those skilled in the art, the bandwidth of the frequency comb 235 extends further than the frequency range shown in FIG. 4, and includes at least f₁ and f₂. The amplitudes of the comb teeth decrease as they approach the limits of the bandwidth of the frequency comb 235. It will be understood that these features are outside the frequency range depicted in FIG. 4, and are not relevant to embodiments of the present invention.

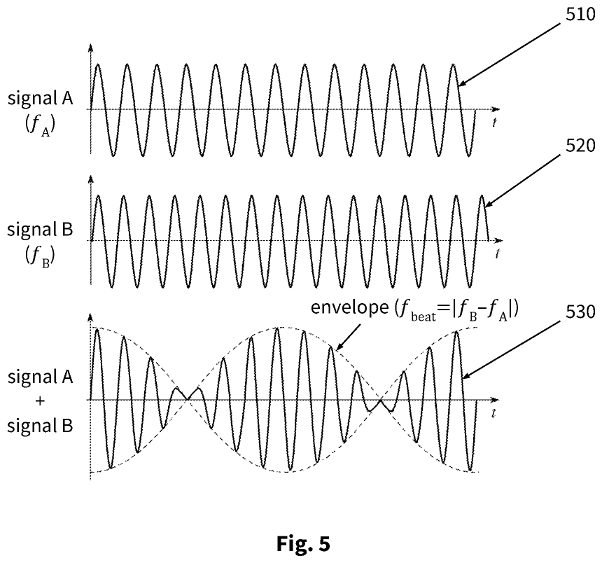

FIG. 5 illustrates the production of a beat signal when two signals of similar frequencies interfere with each other. Note that FIG. 5 shows a general, simplified depiction of beat signal production, and is meant for illustrative purposes only. Therefore, the frequencies and amplitudes shown are not necessarily to scale, and their specific values may not necessarily be in accordance with embodiments of the present disclosure. Signal A, depicted by waveform 510 with frequency f_{A}, and signal B, depicted by waveform 520 with frequency f_{B}, are both pure-tone sinusoids (i.e., they each contain only one respective frequency component). The frequencies of signal A and signal B are such that they are similar in value, but not equal. By way of a non-limiting example, signal A could have a frequency of f_{A}=6 Hz while signal B could have a frequency of f_{B}=7 Hz. The sum of signal A (510) and signal B (520) is depicted by the waveform 530. Because f_{A} and f_{B} are similar in value, they periodically drift between stages of being in-phase and out-of-phase with each other, resulting in constructive interference and destructive interference, respectively, between the two signals. This results in the periodic envelope of the waveform 530 illustrated in FIG. 5 by the dashed line. The distinct, periodic shape of the envelope results in a so-called “beat note,” wherein the frequency of the beat note f_{beat} (also referred to herein as the beat frequency) is given by the difference between f_{A} and f_{B}, i.e., f_{beat}=|f_{B}−f_{A}|. Therefore, given the non-limiting example scenario in which f_{A}=6 Hz and f_{B}=7 Hz, the beat note would have a frequency of f_{beat}=|7 Hz−6 Hz|=1 Hz.

Returning now to FIG. 2, the frequency comb 235 is input to two optical mixers 240A and 240B which are configured to mix the frequency comb 235 with the optical signals 215A and 215B, respectively. In some embodiments, the optical mixers 240A and 240B can comprise 50:50 beamsplitters that are configured to interfere the frequency comb 235 with the optical signals 215A and 215B. In some embodiments, the optical mixers 240A and 240B can further comprise homodyne detectors 242A and 242B that are configured to produce the output beat signals 245A and 245B, respectively. The beat signals 245A and 245B are radio-frequency or microwave electrical signals representing the beat frequency, i.e., they represent the envelope of the optical signals being interfered at each respective optical mixer as illustrated by 530 in FIG. 5.

Both beat signals 245A and 245B are input to a phase measurement device 250A. Beat signal 245B is also input to a second phase measurement device 250B, as is a reference signal 265 generated by a reference source 260. Recall that the phase ϕ of a signal is given by ϕ=2πft+φ, where f is the frequency, t is time, and φ is the phase offset. In some embodiments, the phase measurement devices 250A and 250B can each be one of a radio-frequency/microwave demodulator/mixer (e.g., Analog Devices AD8343), phase-frequency detector (e.g., Analog Devices HMC439), and fully assembled turnkey device (e.g., Toptica mFALC, Vescent D2-135). Further, in some embodiments, the reference source 260 can be one of a radio-frequency reference source and a microwave reference source, and the reference signal 265 can respectively be one of a radio-frequency reference signal and a microwave reference signal. Optionally, if working in the digital domain, the phase measurement devices 250A and 250B can further comprise analog-to-digital converters (ADCs) 252A and 252B that are configured to receive the analog beat signals 245A and 245B, respectively, and convert them to digital signals before the phase measurement is performed.

The phase measurements from 250A and 250B, respectively labelled 255A and 255B in FIG. 2, can subsequently be sent to a signal processor 270. The phase measurements 255A and 255B can comprise either analog or digital signals. The signal processor 270 can be a field-programmable gate array (FPGA) (e.g., Spartan 7), an application-specific integrated circuit (ASIC), or an analog controller (e.g., Newport LB1005-S high-speed servo controller). The signal processor can then be used to control the phase (i.e., both the frequency and the phase offset) of the optical sources 210A and 210B via feedback signals 275A and 275B sent to the frequency controllers 212A and 212B, respectively. Therefore, the system 200 allows for the control of the phase relationship between the optical signal 215B and the comb source signal 225 with respect to the reference signal 265, and for the control of the phase relationship between the optical signal 215A and the comb source signal 225 with respect to the phase relationship between the optical signal 215B and the comb source signal 225.

Note that in other embodiments, the frequencies of the optical signals 215A and 215B may instead have the relationship f₁>f₂, such that f₁>fₛ>f₂, mutatis mutandis.

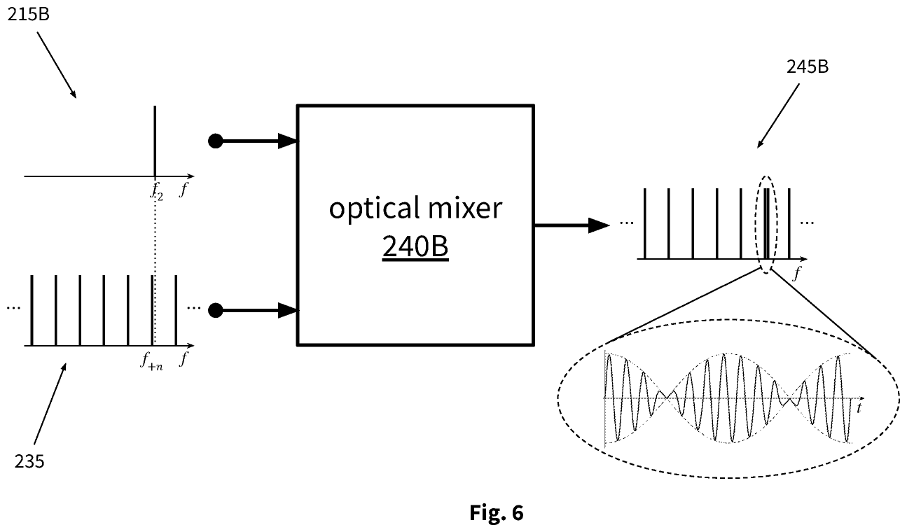

FIG. 6 illustrates the operation of optical mixer 240B from FIG. 2. Note that a similar description to the following could also apply to optical mixer 240A, mutatis mutandis. The optical mixer 240B receives optical signal 215B with frequency f₂ and frequency comb 235. One tooth of the frequency comb 235 has frequency f₊ₙ with a similar (but not equal) value to f₂. The output of the optical mixer 240B is the beat signal 245B, which is a superposition of the two inputs 215B and 235. As described above with reference to FIG. 5, the two frequency components at f₂ and f₊ₙ produce a beat with a distinct periodic envelope, as indicated by the dashed ovals. The beat frequency is directly related to the aforementioned frequency values, i.e., f_{beat}=|f₂−f₊ₙ|. In principle, the other frequency components of the beat signal 245B also interfere with one another to produce beats. One can consider f_{beat} to be the primary beat frequency, with secondary beat frequencies at values of kf_{c}±f_{beat}, where k is a positive integer. However, in some embodiments, f_{c} may be in the range of 10's of MHz to 10's of GHz (e.g., 30 GHz), while f_{beat} may be in the range of a few MHz to a few GHz (e.g., 5 GHz) such that f_{beat}<f_{c}/2. Therefore, the secondary beat frequencies occupy a higher frequency range and are distinct from the primary beat frequency (which is the beat frequency of interest). For example, the phase measurement devices 250A and 250B may be designed and/or configured to be sensitive to a lower range of beat frequencies. Alternatively or in addition, lowpass frequency filters may be used to filter out the secondary beat frequencies. For these reasons, the primary beat frequency is referred to simply as the beat frequency herein.

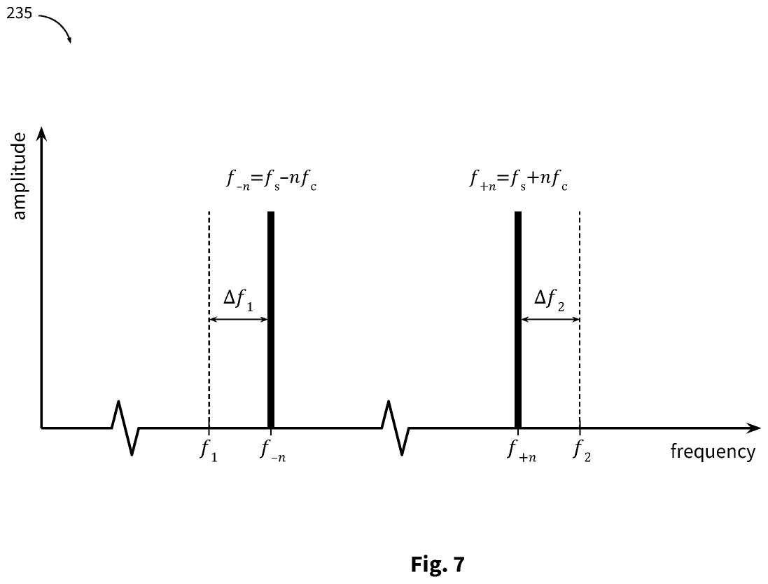

FIG. 7 illustrates a magnified view of the frequency spectrum of frequency comb 235. In particular, FIG. 7 shows the frequency spectrum near the frequencies of the optical signals 215A and 215B (i.e., near f₁ and f₂). f₁ and f₂ are indicated by the dashed vertical lines, while f₊ₙ and f₋ₙ are indicated by the solid vertical lines and represent the comb teeth of the frequency comb 235 that are nearest to the optical signal frequencies. All other comb teeth are not shown for clarity and ease of reference. In accordance with embodiments of the present disclosure, the optical frequencies are chosen such that they satisfy the relationship fₛ=(f₁+f₂)/2, i.e., the frequency of the comb source signal 225 is equal to the average of the frequencies of the two optical signals 215A and 215B. Due to the symmetry of the frequency comb 235 about the central frequency fₛ, and the aforementioned relationship between fₛ, f₁, and f₂, the comb teeth f₊ₙ and f₋ₙ are an equal distance away from fₛ. Equivalently, the value of n in the subscripts of f₊ₙ and f₋ₙ is the same. As shown in FIG. 7, Δf₁=|f₁−f₋ₙ| is the frequency difference between f₁ and f₋ₙ, while Δf₂=|f₂−f₊ₙ| is the frequency difference between f₁ and f₊ₙ.

Returning now to FIG. 2, it can be appreciated that the optical mixers 240A and 240B produce beat signals 245A and 245B with beat frequencies equal to Δf₁ and Δf₂, respectively. The phase measurement device 250B can therefore be configured to measure Δf₂ with respect to the reference signal 265. In a similar way, the phase measurement device 250A can be configured to measure Δf₁ with respect to Δf₂. For each measurement device 250A and 250B, the relative frequencies can be measured using the beat frequency of each beat signal, while the relative phases can be measured using the phase of each beat signal. In some embodiments, the phase measurements from 250A and 250B can then be used to determine one or more control signals by way of the signal processor 270 which can subsequently be used to control the optical sources 210A and 210B via their respective frequency controllers 212A and 212B.

In one possible application of the present invention, the frequencies of optical signals 215A and 215B can be controlled such that they maintain the relationship fₛ=(f₁+f₂)/2. In this way, f₁ and f₂ can drift so long as their respective frequency changes are correlated in order to maintain the desired relationship with fₛ. This can be accomplished by maintaining the relationship Δf₁=Δf₂ by way of the phase measurement devices 250A and 250B. As the frequency comb 235 is symmetric about the central frequency fₛ, Δf₁ and Δf₂ can change (as long as Δf₁=Δf₂, i.e., the change is correlated) while maintaining the relationship fₛ=(f₁+f₂)/2. The phase relationship between f₁, f₂, and fₛ can be controlled in a similar manner. It is noted that the frequency is proportional to the time derivative of the phase, as the phase of a signal is given by ϕ=2πft+φ. Therefore, correlated changes in the frequency as described above consequently result in correlated changes in the phase.

This system for controlling the phase of the optical signals 215A and 215B is also resilient to noise induced by the optical modulator 230. Noise in the driving signal 330 can lead to changes in the comb frequency f_{c}. However, these noise-induced changes in f_{c} are symmetric about fₛ. As an illustrative example, consider the case where f_{c}′=f_{c}+f_{δ}, where f_{δ} represents a small fluctuation in the comb frequency f_{c} due to noise. f₊ₙ then becomes f₊ₙ′=fₛ+nf_{c}+nf_{δ}, while f₋ₙ becomes f₋ₙ′=fₛ−nf_{c}−nf_{δ}. Assuming f₁<f₋ₙ and f₂>f₊ₙ as depicted in FIG. 7, one then obtains Δf₁′=f₋ₙ′−f₁=fₛ−nf_{c}−nf_{δ}−f₁=Δf₁−nf_{δ} and Δf₂′=f₂−f₊ₙ′=f₂−fₛ−nf_{c}−nf_{δ}=Δf₂−nf_{δ}. Therefore, if Δf₁=Δf₂, then Δf₁′=Δf₂′. The relationship Δf₁=Δf₂ can therefore be maintained as f_{c} fluctuates due to noise without requiring any form of active noise correction. Note that the same conclusion can be drawn from this example if the assumption f₁>f₋ₙ and f₂<f₊ₙ is made instead.

Recall that in other embodiments, the frequencies of the optical signals 215A and 215B may instead have the relationship f₁>f₂, such that f₁>fₛ>f₂, wherein the above principles apply mutatis mutandis.

In another possible application of the invention, similar principles as those described for maintaining the relationship fₛ=(f₁+f₂)/2 apply, but for cases where the frequencies f₁ and f₂ of the optical signals 215A and 215B are not equidistant from the comb source signal frequency fₛ. For example, consider the case where f₁ is nearest to a comb tooth with frequency f₋ₘ=fₛ−mf_{c} and f₂ is nearest to a comb tooth with frequency f₊ₙ, where m is a positive integer and m≠n. A small fluctuation f_{δ} in the comb frequency f_{c} would then result in Δf₁′=Δf₁−mf_{δ} and Δf₂′=Δf₂−nf_{δ}. Therefore, changes in Δf₁ and Δf₂ due to fluctuations in the comb frequency have the relationship δ(Δf₁)/δ(Δf₂)=m/n, where δ(Δf₁) is the change in Δf₁ due to f_{δ} and δ(Δf₂) is the change in Δf₂ due to f_{δ}. By using this relationship between δ(Δf₁) and δ(Δf₂), if n and m are known, the relationship fₛ=(mf₁+nf₂)/(m+n) can be maintained.

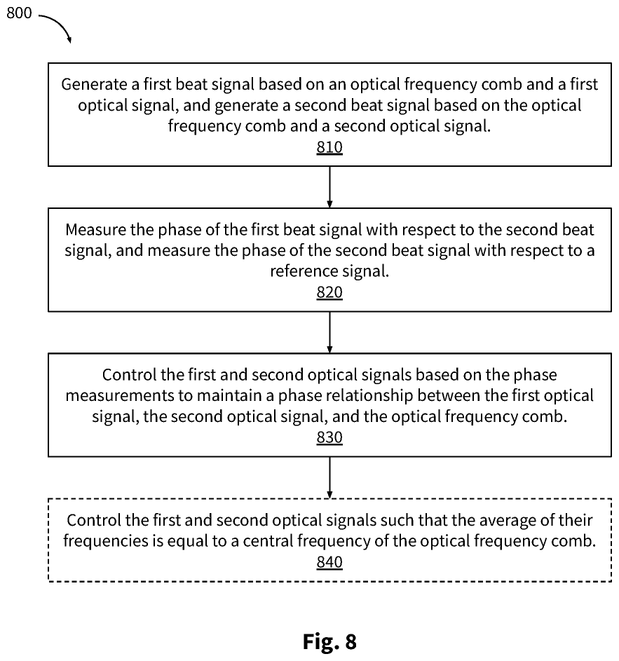

FIG. 8 shows a flowchart for a method 800 for stabilizing the phase of two optical signals using a frequency comb, in accordance with embodiments of the present disclosure. At 810, a first beat signal is generated based on an optical frequency comb and a first optical signal, and a second beat signal is generated based on the optical frequency comb and a second optical signal. In some embodiments, the beat signals may be generated using respective first and second optical mixers comprising 50:50 beamsplitters and homodyne detectors. The beat signals may be radio-frequency or microwave electrical signals, for example.

At 820, the phase of the first beat signal is measured with respect to the second beat signal, and the phase of the second beat signal is measured with respect to a reference signal. The measurements can be performed in either the analog or digital domain. In some embodiments, the phases and frequencies can be measured using radio-frequency/microwave demodulator/mixers (e.g., Analog Devices AD8343), phase-frequency detectors (e.g., OnSemi MC100EP140DG), or fully assembled turnkey devices (e.g., Toptica mFALC, Vescent D2-135). Further, in some embodiments, the reference signal can be one of a radio-frequency signal and a microwave signal.

At 830, the phase measurements from 820 are used to control the first and second optical signals to maintain a phase relationship between the first optical signal, the second optical signal, and the optical frequency comb. For example, in some embodiments the phase measurements can be fed to a signal processor (e.g., FPGA, ASIC, analog controller), which can then produce control signals that are fed back to the optical sources that generate the first and second optical signals.

Optionally, at 840, the controlling from 830 may be done such that the average of the frequencies of the first and second optical signals is equal to a central frequency of the optical frequency comb. For example, in some embodiments, the optical frequency comb may be symmetric about a central frequency. Further, in some embodiments, the central frequency can be a comb source frequency fₛ, and the frequency comb can be generated using an optical modulator such as an electro-optic modulator, for example. This would allow for the controlling of the phase of the first and second optical signals to be resilient to noise induced by the optical modulator.

The steps (also referred to as operations) in the flowcharts and drawings described herein are for purposes of example only. There may be many variations to these steps/operations without departing from the teachings of the present disclosure. For instance, the steps may be performed in a differing order, or steps may be added, deleted, or modified, as appropriate.

In other embodiments, the same approach described herein can be employed for other modalities.

Through the descriptions of the preceding embodiments, the present invention may be implemented by using hardware only, or by using software and a necessary universal hardware platform, or by a combination of hardware and software. The coding of software for carrying out the above-described methods is within the scope of a person of ordinary skill in the art having regard to the present disclosure. Based on such understandings, the technical solution of the present invention may be embodied in the form of a software product. The software product may be stored in a non-volatile or non-transitory storage medium, which can be an optical storage medium, flash drive or hard disk. The software product includes a number of instructions that enable a computing device (personal computer, server, or network device) to execute the methods provided in the embodiments of the present disclosure.

All values and sub-ranges within disclosed ranges are also disclosed. Although the systems, devices, and processes disclosed and shown herein may comprise a specific plurality of elements, the systems, devices, and processes may be modified to comprise additional or fewer of such elements. Although several example embodiments are described herein, modifications, adaptations, and other implementations are possible. For example, substitutions, additions, or modifications may be made to the elements illustrated in the drawings, and the example methods described herein may be modified by substituting, reordering, or adding steps to the disclosed methods.

Features from one or more of the above-described embodiments may be selected to create alternate embodiments comprising a sub-combination of features which may not be explicitly described above. In addition, features from one or more of the above-described embodiments may be selected and combined to create alternate embodiments comprising a combination of features which may not be explicitly described above. Features suitable for such combinations and sub-combinations would be readily apparent to persons skilled in the art upon review of the present disclosure as a whole.

Numerous specific details are set forth to provide a thorough understanding of the example embodiments described herein. It will, however, be understood by those of ordinary skill in the art that the example embodiments described herein may be practiced without these specific details. Furthermore, well-known methods, procedures, and elements have not been described in detail so as not to obscure the example embodiments described herein. The subject matter described herein and in the recited claims intends to cover and embrace all suitable changes in technology.

Although the present invention and its advantages have been described in detail, it should be understood that various changes, substitutions, and alterations can be made herein without departing from the invention as defined by the appended claims.

The present invention may be embodied in other specific forms without departing from the subject matter of the claims. The described example embodiments are to be considered in all respects as being only illustrative and not restrictive. The present disclosure intends to cover and embrace all suitable changes in technology. The scope of the present disclosure is, therefore, described by the appended claims rather than by the foregoing description. The scope of the claims should not be limited by the embodiments set forth in the examples, but should be given the broadest interpretation consistent with the description as a whole.

1. A system comprising:
a first optical source configured to generate a first optical signal;
a second optical source configured to generate a second optical signal;
a first optical mixer configured to generate a first beat signal based on an optical frequency comb and the first optical signal;
a second optical mixer configured to generate a second beat signal based on the optical frequency comb and the second optical signal;
a first detector configured to output a first measurement signal based on the first and second beat signals;
a second detector configured to output a second measurement signal based on the second beat signal and a reference signal; and
a signal processor configured to generate one or more control signals based on the first and second measurement signals for adjusting one or more of the first optical source and the second optical source to maintain a phase relationship between the first optical signal, the second optical signal, and the optical frequency comb.

2. The system of claim 1, wherein
the first optical signal has a first frequency;
the second optical signal has a second frequency;
the first optical mixer is configured to generate the first beat signal based on the first optical signal and a first comb tooth of the optical frequency comb nearest to the first frequency; and
the second optical mixer is configured to generate the second beat signal based on the second optical signal and a second comb tooth of the optical frequency comb nearest to the second frequency.

3. The system of claim 1, further comprising a modulator configured to generate the frequency comb, the frequency comb being symmetric about a comb source frequency.

4. The system of claim 3, wherein
the first optical signal has a first phase ϕ₁ given by ϕ₁=2πf₁t+φ₁, where f₁ is a first frequency, t represents time, and φ₁ is a first phase offset;
the second optical signal has a second phase ϕ₂ given by ϕ₂=2πf₂t+φ₂, where f₂ is a second frequency, t represents time, and φ₂ is a second phase offset; and
the phase relationship is such that the average of the first frequency f₁ and the second frequency f₂ is substantially equal to the comb source frequency.

5. The system of claim 3, wherein the phase relationship is at least partially resilient to noise induced by the modulator.

6. The system of claim 3, wherein the frequency comb is generated based on a local oscillator signal, and the comb source frequency is a local oscillator frequency.

7. The system of claim 1, wherein the first optical mixer comprises a 50:50 beamsplitter and the second optical mixer comprises a 50:50 beamsplitter.

8. The system of claim 1, wherein the first beat signal and second beat signal each comprise a primary beat and a plurality of secondary beats at frequencies greater than the primary beat.

9. The system of claim 1, wherein the reference signal is one of a radio-frequency reference signal and a microwave reference signal.

10. A method comprising:
generating a first beat signal based on an optical frequency comb and a first optical signal;
generating a second beat signal based on the optical frequency comb and a second optical signal;
measuring the phase of the first beat signal with respect to the second beat signal to produce a first phase measurement signal;
measuring the phase of the second beat signal with respect to a reference signal to produce a second phase measurement signal; and
controlling one or more of the first optical signal and the second optical signal based on the first and second phase measurement signals to maintain a phase relationship between the first optical signal, the second optical signal, and the optical frequency comb.

11. The method of claim 10, wherein
the first optical signal has a first frequency;
the second optical signal has a second frequency;
the generating of the first beat signal is based on the first optical signal and a first comb tooth of the optical frequency comb nearest to the first frequency; and
the generating of the second beat signal is based on the second optical signal and a second comb tooth of the optical frequency comb nearest to the second frequency.

12. The method of claim 10, further comprising generating the optical frequency comb such that it is symmetric about a central frequency.

13. The method of claim 12, wherein
the first optical signal has a first phase ϕ₁ given by ϕ₁=2πf₁t+φ₁, where f₁ is a first frequency, t represents time, and φ₁ is a first phase offset;
the second optical signal has a second phase ϕ₂ given by ϕ₂=2πf₂t+φ₂, where f₂ is a second frequency, t represents time, and φ₂ is a second phase offset; and
the phase relationship is such that the average of the first frequency f₁ and the second frequency f₂ is substantially equal to the central frequency.

14. The method of claim 12, wherein the phase relationship is at least partially resilient to noise induced in the generating of the optical frequency comb.

15. The method of claim 10, further comprising filtering one or more of the first beat signal and the second beat signal to remove high-frequency beats.
